(19) United States
(12) Patent Application Publication
(10) Pub. No.: US 2012/0175340 A1
(43) Pub. Date: Jul. 12, 2012

(54) METHOD FOR MANUFACTURING WIRING BOARD

(75) Inventor: Katsunori Misaki, Osaka-shi (JP)

(73) Assignee: SHARP KABUSHIKI KAISHA, Osaka-shi, Osaka (JP)

(21) Appl. No.: 13/395,952

(22) PCT Filed: Apr. 28, 2010
(86) PCT No.: PCT/JP2010/057589

§ 371 Date: Mar. 14, 2012

(30) Foreign Application Priority Data
Sep. 17, 2009 (JP) 2009-215704

(51) Int. Cl. H05K 3/10

(52) U.S. Cl. 216/18; 216/17

(57) ABSTRACT

In order to provide a method for manufacturing a wiring board free from contact fault, a method of the present invention, which manufactures a wiring board (1) including an Al alloy pad (3) on a base layer (2), a gate insulating film (4) and an interlayer insulating film (5) above the Al alloy pad (3), and a contact hole whose opening part reaches a part of the Al alloy pad (3), includes the steps of: forming a contact hole (7) in the gate insulating film (4) and the interlayer insulating film (5) by dry etching so as to expose, in the contact hole (7), at least part of an end part (20) of the Al alloy pad (3) and a part (10) of the base layer (2) which part (10) is adjacent to at least the part of the end part (20); and removing, after forming the contact hole (7), an electrically nonconductive layer (9) caused on a surface of the Al alloy pad (3) by the dry etching.

### TECHNICAL FIELD

The present invention relates to a method for manufacturing a wiring board for use in a display device, etc.

### BACKGROUND ART

A thin film transistor (hereinafter also referred to as TFT) substrate for use in a display device such as a liquid crystal display device, etc. has line layers provided therein, such as gate electrode lines, source electrode lines, drain electrode lines, etc. In view of low resistance, workability, and a manufacturing cost, Al or an Al alloy is generally used to form such electrode lines. Usually, electrode lines are electrically connected with a transparent electrode film as follows: (i) an electrode line layers are formed, (ii) an insulating film is formed on the electrode line layer, (iii) contact holes are opened in the insulating film, and (iv) the transparent electrode film such as ITO (Indium Tin Oxide), etc. is formed (see Patent Literatures 1 to 4, for example).

For example, the patent literature 1 discloses a film forming method for a TFT which film forming method includes the steps of (i) disposing three layers, i.e., a lower aluminum nitride layer, an aluminum layer, and an upper aluminum nitride layer, so as to form an Al line thin film which serves as a gate line thin film or source/drain line thin films, (ii) forming an insulating film on the Al line thin film, (iii) opening a contact hole in the insulating film, and (iv) forming ITO in such a manner that formed ITO is in contact with the Al line thin film.

For example, the patent literatures 2 and 3 disclose methods for manufacturing TFT array substrates each of which methods includes the steps of (i) forming an interlayer insulating film on a gate terminal section and source/drain electrode sections made from pure aluminum or an aluminum alloy, (ii) opening a contact hole in the gate terminal section and the drain electrode section by patterning, and (iii) forming an ITO film.

The patent literature 4 discloses a method for manufacturing a display device which method includes the steps of (i) forming an Al alloy film on a substrate, (ii) forming an interlayer insulating film on the Al alloy film, (iii) forming a contact hole in the interlayer insulating film, and (iv) forming a transparent conductive film in such a manner that it is in contact with the Al alloy film.

### CITATION LIST

### Patent Literature

Patent Literature 1

Japanese Patent Application Publication, Tokukai, No. 2003-273109 A (Publication Date: Sep. 26, 2003)

Patent Literature 2

Japanese Patent Application Publication, Tokukaihei, No. 11-284195 A (Publication Date: Oct. 15, 1999)

Patent Literature 3

Japanese Patent Application Publication, Tokukai, No. 2008-262227 A (Publication Date: Oct. 30, 2008)

Patent Literature 4

Japanese Patent Application Publication, Tokukai, No. 2008-304830 A (Publication Date: Dec. 18, 2008)

### SUMMARY OF INVENTION

### Technical Problem

However, use of an Al alloy as a line material may cause a poor contact, in a case where (i) an insulating film is provided on a line layer made from the Al alloy, (ii) a contact hole is formed in the insulating film, and (iii) an electrically conductive layer is provided in the contact hole. The reason for this is described with reference to FIG. 5.

FIG. 5 is a cross sectional view explaining a method for manufacturing a TFT substrate by using the Al alloy as the line material. (a) through (e) of FIG. 5 schematically show respective conditions of a substrate in the steps of the method.

First, a line layer 103 made from the Al alloy is formed on a base layer 102, and a gate insulating film 104 and an interlayer insulating film 105 are formed above the base layer 102 so as to cover the line layer 103 (see (a) of FIG. 5).

Then, a resist pattern 108 for a contact hole is formed on the interlayer insulating film 105 (see (b) of FIG. 5).

After this, a contact hole 107 is formed in the interlayer insulating film 105 and the gate insulating film 104 by dry etching with a fluorine-containing gas, so that the line layer 103 is revealed (see (c) of FIG. 5). In this case, a surface of that part of the line layer 103 which is revealed in the contact hole 107 forms an electrically nonconductive layer 109 that encompasses a fluorinated and/or oxidized layer of the Al alloy, etc. The electrically nonconductive layer 109 spreads not only in a revealed part of the line layer 103, but also to a part that surrounds the revealed part below a canopy-like edge of the gate insulating film 104. The resist pattern 108 is removed after the dry etching.

Both the fluorinated layer of the Al alloy and the oxidized layer of the Al alloy are nonconductive and thereby block an electric connection. In view of this, the electrically nonconductive layer 109 is removed by a chemical solution such as an alkaline fluid, etc. after the dry etching (see (d) of FIG. 5). However, this causes a boundary between the line layer 103 and the gate insulating film 104 in the contact hole 104 to form an overhang 111 (see (d) of FIG. 5). This is because the electrically nonconductive layer 109 extends even to the part that surrounds the revealed part of the line layer 103 and is coated with the gate insulating film 104 (see (c) of FIG. 5).

In a case where a transparent electrode film 106 is provided in a contact-hole-107 part of a circuit board 101 thus formed, a part forming the overhang 111 forms a stepwise disconnection 112 (see (e) of FIG. 5). This causes a poor contact.

Meanwhile, according to a thin film structure of the patent literature 1, a formation of insulating aluminum oxide is prevented by providing the Al nitride layer above the Al layer. However, the Al nitride layer is easy to form a electrically nonconductive layer for the following reasons; it is difficult to control a nitriding degree and a thickness of the Al nitride layer, thereby making it difficult to control a specific resistance of the Al nitride layer. This causes a problem of occurrence of the poor contact.

The present invention is made in view of the problem, and an object of the present invention is to provide a method for manufacturing, without forming an Al nitride layer that is difficult to be controlled, a wiring board capable of surely securing a stable contact.

### Solution to Problem

In order to attain the object, a method of the present invention for manufacturing a wiring board including an Al alloy layer provided on a base layer, an insulating layer provided on the Al alloy layer, and a contact hole whose opening part reaches a part of the Al alloy layer, said method including the steps of: (i) forming the contact hole in the insulating layer by etching so as to expose, in the contact hole, (a) at least a first part of an end of the Al alloy layer and (b) a second part of the base layer, the second part being adjacent to at least the first part; and (ii) removing, after the step (i), an electrically nonconductive layer, caused by the etching, on a surface of the Al alloy layer.

A disconnection, which causes contact fault, is caused by an overhang caused at a boundary between the Al alloy layer and the insulating layer in the contact hole. The overhang is caused in a region of the Al alloy layer which surrounds an exposed part and is covered with an insulating film, by removing an electrically nonconductive layer caused on a surface of the Al alloy layer by the etching for the contact hole. This is because the electrically nonconductive layer to be removed extends to the region.

According to the arrangement, however, the contact hole is formed in the insulating layer covering the Al alloy layer above the base layer, by applying etching so as to expose, in the contact hole, (a) at least the first part of the end of the Al alloy layer and (b) the second part of the base layer, the second part being adjacent to at least the first part. Further, an electrically conductive part of the Al alloy layer is exposed by removing the electrically nonconductive layer caused on the surface of the Al alloy layer while the contract hole is being formed. This allows electric contact with the Al alloy layer.

According to the arrangement the following insulating layers (i) and (ii) are removed when the contact hole is formed; (i) the insulating layer which covers the end part of the Al alloy layer and (ii) the insulating layer which covers the part of the base layer which part is adjacent to the end part of the Al alloy layer. As such, on a side of the end part, there is no boundary between the Al alloy layer and the insulating layer in the contact hole, resulting in that an electrically nonconductive layer in the region covered with the insulating layer, as early described, is not caused. On this account, it is possible to avoid formation of an overhang which may be caused by removing the electrically nonconductive layer. As such, there is no formation of stepwise disconnection caused by the overhang. It is therefore possible to avoid an occurrence of contact fault.

In order to attain the object, a method of the present invention for manufacturing a wiring board is a method for manufacturing a wiring board including an Al alloy layer provided on a base layer, a plurality of insulating layers provided on and above the Al alloy layer, and a contact hole whose opening part reaches the Al alloy layer, said method including the steps of: (i) forming, after forming a first insulating layer of the plurality of insulating layers, a first hole in the first insulating layer by etching so as to expose a first part of the Al alloy layer in the first hole; and (ii) forming by etching, after forming a second insulating layer of the plurality of insulating layers on the first insulating layer so as to cover an exposed surface of the Al alloy layer, a second hole in the second insulating layer located within the first hole so as to expose a second part which is part of the first surface of the Al alloy layer thus exposed, an electrically nonconductive layer, caused by the etching on the surface of the Al alloy layer in the step (i), being removed in the step (i), an electrically nonconductive layer, caused by the etching on the surface of the Al alloy layer in the step (ii), being removed in the step (ii).

A disconnection, which causes contact fault, is caused by an overhang caused at a boundary between the Al alloy layer and the insulating layer in the contact hole. The overhang is caused in a region of the Al alloy layer which surrounds an exposed part and is covered with an insulating film, by removing an electrically nonconductive layer caused on a surface of the Al alloy layer by the etching for the contact hole. This is because the electrically nonconductive layer to be removed extends to the region. A size of a region, where the electrically nonconductive layer is caused on the part of the Al alloy layer which surround the exposed part and is covered with the insulating film, varies depending on time required for etching. The thicker the insulating layer to which the etching is performed is, the longer the time required for the etching is. This increases the size of the region where the electrically nonconductive layer is caused in the part of the Al alloy layer which part surrounds the exposed part and is covered with the insulating layer. The greater the size of the region is, the greater the degree of the overhang becomes, thereby making it easier that the disconnection is caused when an electrically conductive layer is provided within the contact hole.

According to the arrangement, (i) the insulating layers stacked above the Al alloy layer are multiple insulating layers provided independently from each other, (ii) a contact hole in which the part of the Al alloy layer is exposed is formed each time a corresponding one of the insulating layers is formed, and (iii) the electrically nonconductive layer caused on the surface of the Al alloy layer is removed. A thickness of each insulating layer in which a corresponding contact hole is formed is thinner as compared with a combined thickness of the entire insulating layers. On this account, time required for each etching applied to a corresponding one of the insulating layers to form a contact hole is less than time required for etching applied to the entire insulating layers to form a common contact hole. This decreases a range of the electrically nonconductive layer which range is caused on the Al alloy layer in the region surrounding the exposed part and being covered with the insulating films. This in turn more decreases a degree of the overhang caused by the removal of the electrically nonconductive layer.

Therefore, in a case where an electrically conductive layer is provided in the contact hole thus formed, the disconnection is rarely caused, and occurrence of contact fault can be prevented.

### Advantageous Effects of Invention

A method of the present invention for manufacturing a wiring board thus (i) forms a contact hole in an insulating layer by dry etching so as to expose, in the contact hole, (a) at least a first part of an end of an Al alloy layer and (b) a second part of a base layer for the Al alloy layer, the second part being adjacent to at least the first part, and then (ii) removes an electrically nonconductive layer caused on a surface of the Al alloy layer. This makes it possible to avoid occurrence of an overhang, which is a causal of disconnection, in an end part of the Al alloy layer. As such, it is possible to avoid occurrence of contact fault in an electrically conductive layer.

Also, a method of the present invention for manufacturing a wiring board (i) forms, after forming a first insulating layer of a plurality of insulating layers, a first hole in the first insulating layer by dry etching so as to expose a first part of an Al alloy layer in the first hole, and (ii) forms by dry etching, after forming a second insulating layer of the plurality of insulating layers on the first insulating layer so as to cover an exposed surface of the Al alloy layer, a second hole in the second insulating layer located within the first hole so as to expose a second part which is part of the first part of the Al alloy layer thus exposed, and an electrically nonconductive layer caused, by each of the etchings, on the surface of the Al alloy layer is removed each time it is caused while a corresponding one of the first and second holes is formed. This decreases a degree of an overhang causable while the first and second holes are being formed. As such, it is possible to prevent occurrence of disconnection caused due to the overhang. This makes it possible to avoid occurrence of contact fault in an electrically conductive layer.

### BRIEF DESCRIPTION OF DRAWINGS

FIG. 1 is a cross sectional view schematically showing an arrangement of a wiring board in accordance with one embodiment of the present invention.

FIG. 2 is a view explaining, in an order from (a) to (e) of FIG. 2, steps of a manufacturing method of a wiring board in accordance with one embodiment of the present invention. (a) to (e) of FIG. 2 show conditions in the respective steps of the manufacturing method.

FIG. 3 is a cross sectional view schematically showing an arrangement of a wiring board in accordance with another embodiment of the present invention.

FIG. 4 is a view explaining, in order from (a) through (g) of FIG. 4, steps of a manufacturing method of a wiring board in accordance with another embodiment of the present invention. (a) through (g) of FIG. 4 show conditions in the respective steps of the manufacturing method.

FIG. 5 is a view explaining, in order from (a) through (e) of FIG. 5, steps of a conventional manufacturing method of a wiring board. (a) through (e) of FIG. 5 show conditions in the respective steps of the conventional manufacturing method.

### DESCRIPTION OF EMBODIMENTS

### Embodiment 1

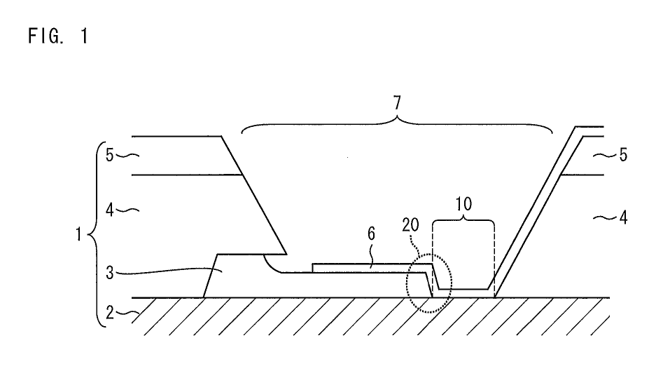

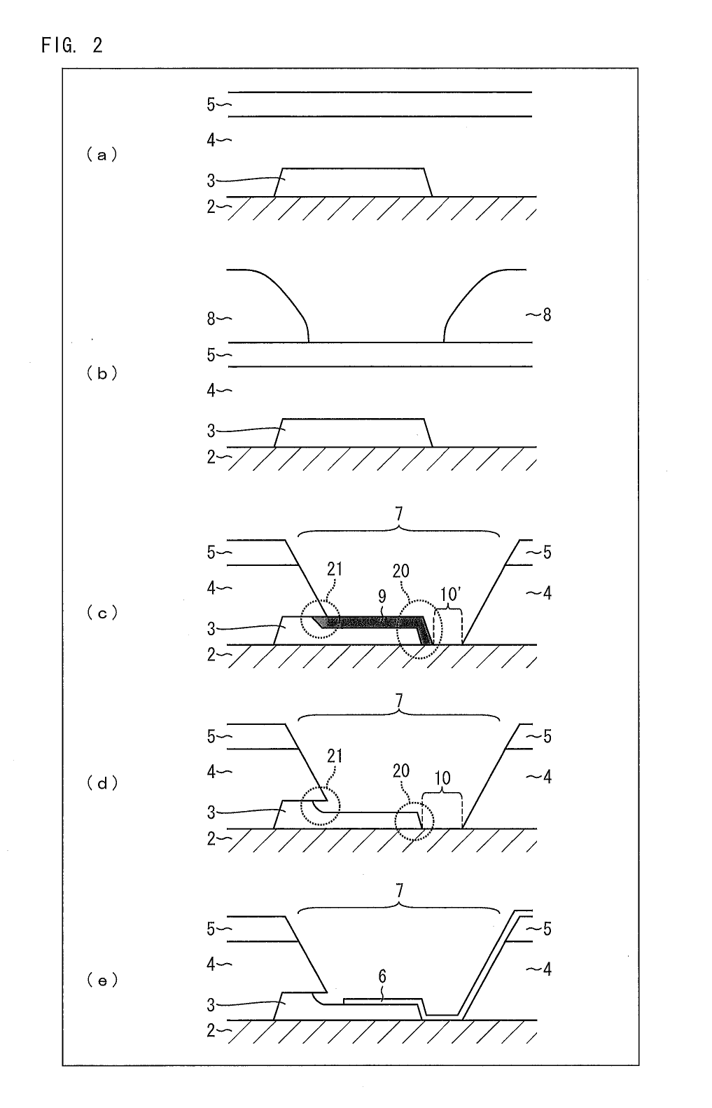

One embodiment of the present invention is described below with reference to FIGS. 1 and 2.

FIG. 1 is a cross sectional view schematically showing an arrangement of a wiring board manufactured by a manufacturing method of the present embodiment.

In a wiring board 1, the following members (i) through (iv) are provided on and above a base layer 2, (i) an Al alloy pad 3, (ii) a gate insulating film 4, (iii) an interlayer insulating film 5, and (iv) a transparent electrode film 6 (see FIG. 1).

The wiring board 1 is used as a wiring board in a display device, such as a TFT (thin film transistor) substrate of a liquid crystal panel.

The base layer 2 serves as a base layer on which the Al alloy pad 3 is provided. The base layer 2 can be, but not limited to, an insulating layer or the like. Alternatively, the base layer 2 can be an insulating substrate such as a glass substrate. It is preferable that the base layer 2 is made from (i) a material which is not corroded during an alkali treatment or (ii) a material which causes no compound layer, which can be corroded during an alkali treatment, to be formed on a surface of the base layer 2 during dry etching using a fluorine-containing gas. This is because, as later described, the base layer 2 is partially exposed by the dry etching before the alkali treatment. From this perspective, the base layer 2 can be made from glass or an inorganic insulating film such as SiO₂ or amorphous Si, for example.

The Al alloy pad 3 is an electrically conductive layer. The Al alloy pad 3 is used to form metal lines, such as a gate line and a source/drain line, and metal electrode sections, such as a gate electrode and a source/drain electrode. An Al alloy prepared by adding, to Al, one or more of Ni, Cu, La, Ge, Nd, and B can be used as an Al alloy, for example.

In the wiring board 1, a contact hole 7, whose opening part reaches a part of the Al alloy pad 3, is provided in both of the gate insulating film 4 and the interlayer insulating film 5. The contract hole 7 is configured so as to allow electric connection between the Al alloy pad 3 and the transparent electrode film 6 provided on the interlayer insulating film 5.

As shown in FIG. 1, in the wiring board 1, the following (i) and (ii) are exposed in the contact hole 7 before the transparent electrode film 6 is formed, (i) the Al alloy pad 3 and (ii) a region 10, which is part of the base layer 2 and is adjacent to part of an end (hereinafter also simply referred to as an end part) 20 of the Al alloy pad 3. The transparent electrode film 6 is continuously provided on (i) the interlayer insulating film 5, (ii) a wall surface of the contact hole 7, (iii) the region 10 which is exposed in the contact hole 7, and (iv) the end part 20 of the Al alloy pad 3.

FIG. 2 is a view showing how steps of the manufacturing method of the present embodiment are sequentially carried out. The manufacturing method of the present embodiment manufactures a wiring board including an Al alloy layer provided on a base layer, an insulating layer provided on the Al alloy layer, and a contact hole whose opening part reaches a part of the Al alloy layer. Specifically, the method includes the steps of (i) forming the contact hole in the insulating layer by dry etching so as to expose, in the contact hole, (a) at least a first part of an end of the Al alloy layer and (b) a second part of the base layer which second part is adjacent to at least the first part, and (ii) removing, after forming the contact hole, an electrically nonconductive layer, caused by the dry etching, on a surface of the Al alloy layer. With the method, the wiring board 1 shown in FIG. 1 can be suitably manufactured. The manufacturing method of the present embodiment is described below in detail, with reference to FIG. 2.

First, the Al alloy pad 3 is formed on the base layer 2 by use of a conventionally known method such as sputtering or photolithography. Then, the gate insulating film 4 and the interlayer insulating film 5 are formed, in this order, on the base layer 2 by use of a conventionally known method such as CVD (chemical vapor deposition) so as to cover the Al alloy pad 3 (see (a) of FIG. 2). The gate insulating film 4 and the interlayer insulating film 5 are made from silicone nitride and have film thicknesses of 350 nm and 200 nm, respectively.

After formation of the interlayer insulating film 5, a resist pattern 8 is formed, on the interlayer insulating film 5, so as to form the contact hole 7 (see (b) of FIG. 2). In the present embodiment, the resist pattern 8 is formed on the interlayer insulating film 5 such that both of the following (i) and (ii) will be exposed by etching, (i) the Al alloy pad 3 and (ii) a region 10′ which is part of the base layer 2 and which is adjacent to the end part 20 of the Al alloy pad 3. That is, the resist pattern 8 for the etching is formed on the interlayer insulating film 5 such that the etching causes the end part 20 of the Al alloy pad 3 and the partial region 10′ of the base layer 2 to be exposed in the opening part of the contact hole 7.

After formation of the resist pattern 8, the contact hole 7 is formed by the dry etching in which the fluorine-containing gas is used, and then the resist patter 8 is removed (see (c) of FIG. 2).

In the present embodiment, the dry etching is made for the contact hole 7 under the following conditions: an etching gas is SF₆/O₂, a gas flow rate is SF₆/O₂=[100 to 800]/[100 to 800] (sccm), a pressure is 3 Pa to 60 Pa, and an RF power is 300 W to 1200 W. Further, oxygen ashing is applied so as to remove residual fluorine left outside the contact hole 7. The oxygen ashing is made, for example, under the following conditions: a gas flow rate of an O₂ gas is 100 sccm to 800 sccm, a pressure is 5 Pa to 40 Pa, and an RF power is 300 W to 1200 W.

The dry etching causes both of (i) the Al alloy pad 3 and (ii) the region 10′ of the base layer 2, which region 10′ is adjacent to the end part 20 of the Al alloy pad 3, to be exposed. However, the dry etching causes formation of an electrically nonconductive layer 9, such as a fluorinated layer of and/or an oxidized layer of the Al alloy, in a region on the surface of the Al alloy pad 3 to be exposed. Note that the electrically nonconductive layer 9 formed on the Al alloy pad 3 extends, at a boundary part 21 between the gate insulating film 4 and the Al alloy pad 3 in the contact hole 7, to a region of the Al alloy pad 3 which region is located below an edge part of the gate insulating film 4, i.e., to a region which is still covered with the gate insulating film 4 even after the formation of the contact hole 7 (see (c) of FIG. 2).

Since the electrically nonconductive layer 9 blocks an electric conduction, it is removed by using a chemical solution such as an alkali fluid (see (d) of FIG. 2). This causes an overhang, at the boundary part 21 between the gate insulating film 4 and the Al alloy pad 3, in which the gate insulating film 4 overhangs the Al alloy pad 3. Note that, with the removal of the electrically nonconductive layer 9, an exposed part of the Al alloy pad 3 is followed by the region 10 of the base layer 2 which is now exposed in the end part 20 of the Al alloy pad 3. A boundary with the gate insulating film 4 in the contact hole 7 is located in the region 10. In this case, no overhang is formed in the following regions (i) and (ii), (i) a region where the region 10 abuts the end part 20 and (ii) a region where the region 10 abuts the gate insulating film 4.

Note that the alkali solution is not limited to a specific one, provided that it can dissolve an Al fluoride and an Al oxide. As such, an ammonia water or an ammonia ionic water can be used as the alkali solution, for example.

Then, the transparent electrode film 6, such as an ITO (indium tin oxide) film, is deposited by sputtering so as to be in contact with the Al alloy pad 3 in the contact hole 7 thus formed (see (e) of FIG. 2). The transparent electrode film 6 is formed on the interlayer insulating film 5 and in the contact hole 7. In this case, since no overhang is formed in a region near the region 10, the transparent electrode film 6 is continuously formed on the Al alloy pad 3, the region 10, and the wall surface of the contact hole 7.

It follows that, since there occurs no disconnection in a case where the transparent electrode film 6 is formed, it is possible to avoid occurrence of contact fault in the contact hole 7.

### Embodiment 2

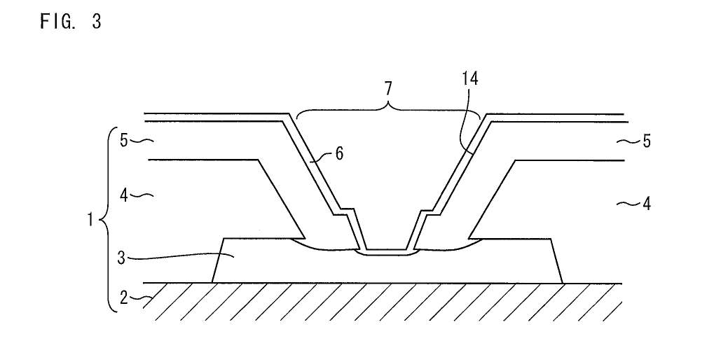

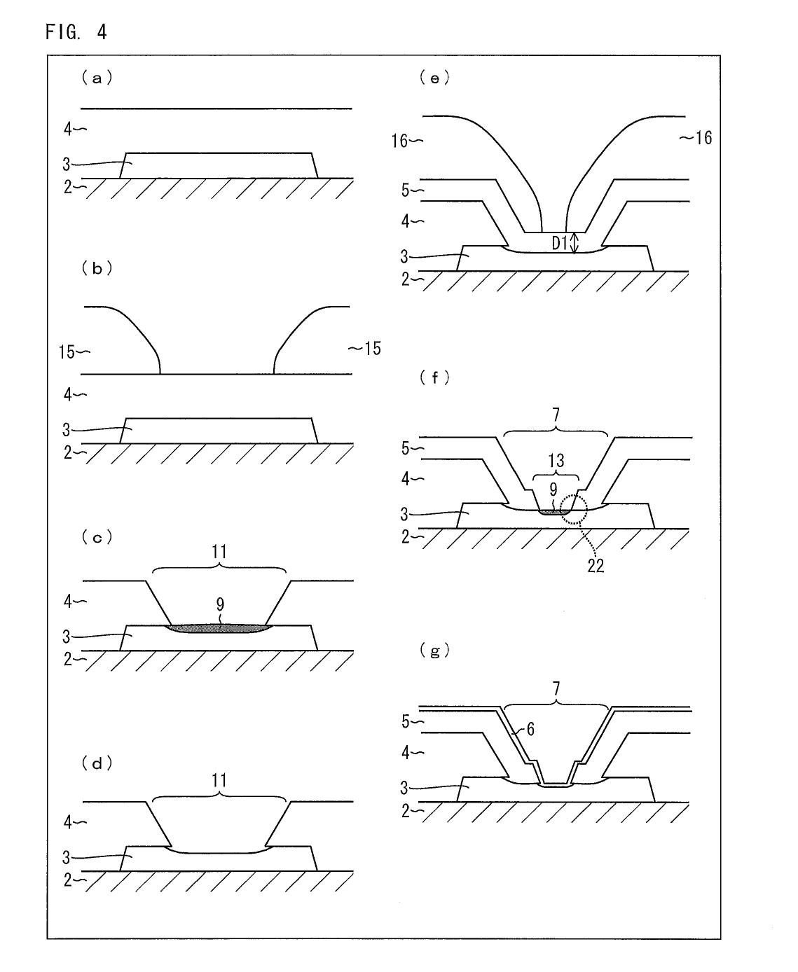

Embodiment 2 of the present invention is described below with reference to FIGS. 3 and 4. For convenience, members having functions identical to those of the members described in Embodiment 1 are given identical reference numerals, and their descriptions are omitted.

FIG. 3 is a cross sectional view schematically showing an arrangement of a wiring board manufactured by a manufacturing method of the present embodiment.

Unlike the wiring board 1 of Embodiment 1, a wiring board 1 of Embodiment 2 is arranged such that only an Al alloy pad 3, out of the Al alloy pad 3 and a base layer 2, is partially exposed in a contact hole 7 prior to formation of a transparent electrode film 6 (see FIG. 3). Also, a wall surface 14 of the contact hole 7 is formed by an interlayer insulating film 5. An insulating film 4 is covered with the interlayer insulating film 5 in the contact hole 7.

FIG. 4 is a view explaining how steps of the manufacturing method of the present embodiment are sequentially carried out. The manufacturing method of the present embodiment manufactures a wiring board including an Al alloy layer provided on a base layer, a plurality of insulating layers provided on and above the Al alloy layer, and a contact hole whose opening part reaches the Al alloy layer. Specifically, the method includes the steps of: (i) forming, after forming a first insulating layer of the plurality of insulating layers, a first hole in the first insulating layer by etching so as to expose a first part of the Al alloy layer in the first hole; and (ii) forming by etching, after forming a second insulating layer of the plurality of insulating layers on the first insulating layer so as to cover an exposed surface of the Al alloy layer, a second hole in the second insulating layer located within the first hole so as to expose a second part which is part of the first surface of the Al alloy layer thus exposed. An electrically nonconductive layer, which is caused (generated) on the surface of the Al alloy layer each time the etching is applied, is removed each time it is caused by a corresponding one of the first and second holes being formed. That is, (i) an electrically nonconductive layer, which is caused on the surface of the Al alloy layer in the etching for the first hole, is removed in the step of forming the first hole, and (ii) an electrically nonconductive layer, which is caused on the surface of the Al alloy layer in the etching for the second hole, is removed in the step of forming the second hole. The method for manufacturing the wiring board is described below with reference to FIG. 4. Note that the present embodiment deals with a case where the gate insulating film 4 and the interlayer insulating film 5, each of which is a single layer, are stacked on the Al alloy pad 3. However, the present embodiment is not limited to this. Therefore, three or more insulating films can be stacked on the Al alloy pad 3.

First, the Al alloy pad 3 is formed on the base layer 2 by use of a conventionally known method such as sputtering or photolithography. Then, the gate insulating film 4, which is made from silicone nitride and has a film thickness of 350 nm, is formed on and above the base layer 2 by use of a conventionally known method such as CVD so as to cover the Al alloy pad 3 (see (a) of FIG. 4).

After formation of the gate insulating film 4, a resist pattern 15 is formed on the gate insulating film 4 so as to form a hole 11 in the gate insulating film 4 above the Al alloy pad 3 (see (b) of FIG. 4).

After formation of the resist pattern 15, the hole 11 is formed by dry etching in which a fluorine-containing gas is used, and then the resist pattern 15 is removed (see (c) of FIG. 4).

In the present embodiment, the dry etching is made for the hole 11 under the following conditions: an etching gas is SF₆/O₂, a gas flow rate is SF₆/O₂=[100 to 800]/[100 to 800] (sccm), a pressure is 3 Pa to 6 Pa, and an RF power is 300 W to 1200 W. Further, oxygen ashing is applied so as to remove residual fluorine left outside the hole 11. The oxygen ashing is made, for example, under the following conditions: a gas flow rate of an O₂ gas is 100 sccm to 800 sccm, a pressure is 5 Pa to 40 pa, and an RF power is 300 W to 1200 W.

However, the dry etching causes formation of an electrically nonconductive layer 9, such as a fluorinated layer of and/or an oxidized layer of an Al alloy, in a region on the surface of the Al alloy pad 3 to be exposed.

Since the electrically nonconductive layer 9 blocks an electric conduction, it is removed by using a chemical solution such as an alkali fluid (see (d) of FIG. 4).

Then, the interlayer insulating film 5 is formed by use of a conventionally known method such as CVD so as to cover the gate insulating film 4 and an exposed part of the Al alloy pad 3. The interlayer insulating film 5 thus formed is made from silicone nitride and has a film thickness of 200 nm. A resist pattern 16 is formed on the interlayer insulating film 5 except for a part of the interlayer insulating film 5 directly above the Al alloy pad 3 (see (e) of FIG. 4) such that the hole 13 is further formed in the part of the interlayer insulating film 5 within the hole 11.

The hole 13, after formation of the resist pattern 16, is formed in the interlayer insulating film 5 by dry etching in which the fluorine-containing gas is used, and then the resist pattern 16 is removed (see (f) of FIG. 4).

In the present embodiment, the dry etching is made for the hole 13 under the following conditions: an etching gas is CF₄/O₂, a gas flow rate is CF₄/O₂=[100 to 800]/[100 to 800] (sccm), a pressure is 3 Pa to 60 Pa, and an RF power is 300 W to 1200 W. Further, oxygen ashing is applied so as to remove residual fluorine left outside the hole 13. The oxygen ashing is made, for example, under the following conditions: a gas flow rate of an O₂ gas is 100 sccm to 800 sccm, a pressure is 5 Pa to 40 Pa, and an RF power is 300 W to 1200 W.

Note that the conditions of the dry etching for forming the hole 13 can be identical to those of the dry etching for forming the hole 11. However, a film thickness of the electrically nonconductive layer 9 becomes thinner in a case where the CF₄/O₂ gas is used than in a case where SF₆/O₂ gas is used. This causes a decrease in degree of an overhang (later described). It is therefore desirable, from a perspective of preventing occurrence of a disconnection caused by the overhang, to use the CF₄/O₂ gas as the etching gas during the etching for forming the hole 13 in the interlayer insulating film 5 (i.e., an outermost layer).

Note that, if the interlayer insulating film 5 has a film thickness of less than 200 nm, then no oxygen ashing is needed.

Note that the dry etching causes formation of an electrically nonconductive layer 9, such as a fluorinated layer of and/or an oxidized layer of the Al alloy, in a region on the surface of the Al alloy pad 3 thus exposed (see (f) of FIG. 4).

Because the electrically nonconductive layer 9 blocks an electric conduction, it is removed by using the chemical solution such as the alkali fluid, as early described.

Thus, the contact hole 7 whose opening part reaches the Al alloy pad 3 is defined by (i) the interlayer insulating film 5 which forms the wall surface of the hole 11 in the gate insulating film 4 and (ii) the hole 13 formed in the interlayer insulating film 5 located within the hole 11.

Then, the transparent electrode film 6 such as an ITO film is deposited by sputtering so as to be in contact with the Al alloy pad 3 in the contact hole 7 (see (g) of FIG. 4).

The electrically nonconductive layer 9 thus formed on the Al alloy pad 3 extends, at a boundary part 22 between the interlayer insulating film 5 and the Al alloy pad 3 in the hole 13, to a region of the Al alloy pad 3 which region is located below an edge part of the interlayer insulating film 5, i.e., to a region which is still covered with the interlayer insulating film 5 even after the formation of the hole 13. Therefore, the removal of the electrically nonconductive layer 9 with the use of the chemical solution causes, at the boundary part 22 between the interlayer insulating film 5 and the Al alloy pad 3 in the hole 13, an overhang in which the interlayer insulating film 5 overhangs the Al alloy pad 3.

In the present embodiment, however, even if the overhang is caused at the boundary part 22 in the contact hole 7, the transparent electrode film 6 has no disconnection when being formed in the contact hole 7. As such, it is possible to prevent occurrence of contact fault. The reason for this is described below.

The disconnection, which causes the contact fault, is caused by an overhang caused at a boundary between the following (i) and (ii) in the contact hole 7, (i) the Al alloy pad 3 and (ii) an insulating film (the interlayer insulating film 5 in the present embodiment) forming the wall surface 14 of the contact hole 7. The overhang is caused in the region located below the edge part of the interlayer insulating film 5, by removing the electrically nonconductive layer 9 thus caused on the surface of the Al alloy pad 3 by the dry etching for the hole 13. This is because the electrically conductive layer 9 to be removed extends to the region located below the edge part of the interlayer insulating film 5, i.e., to a surrounding region surrounding the exposed part of the Al alloy pad 3 which surrounding region is still covered with the interlayer insulating film 5 even after formation of the hole 13. As such, a degree of the overhang is related with a size of a part of the electrically nonconductive layer 9 which part extends below the overhanging edge part of the interlayer insulating film 5.

The size of the electrically nonconductive layer 9 varies depending on time required for etching. That is, the longer the time required for etching is, the thicker the electrically nonconductive layer 9 is, which causes the electrically nonconductive layer 9 to extend even to the region located below the edge part of the interlayer insulating film 5. Further, the longer the time required for etching is, the larger an area of the electrically nonconductive layer 9 which is formed in the region located below the edge part of the interlayer insulating film 5 is. The thicker a layer to be subjected to the etching is, the longer the time required for the etching is. This causes an increase in the area of the electrically nonconductive layer 9. The larger the area of the electrically nonconductive layer 9 is, the larger the degree of the overhang is. This causes the disconnection to easily occur in a case where a transparent electrode film is formed on a wall surface in the contact hole.

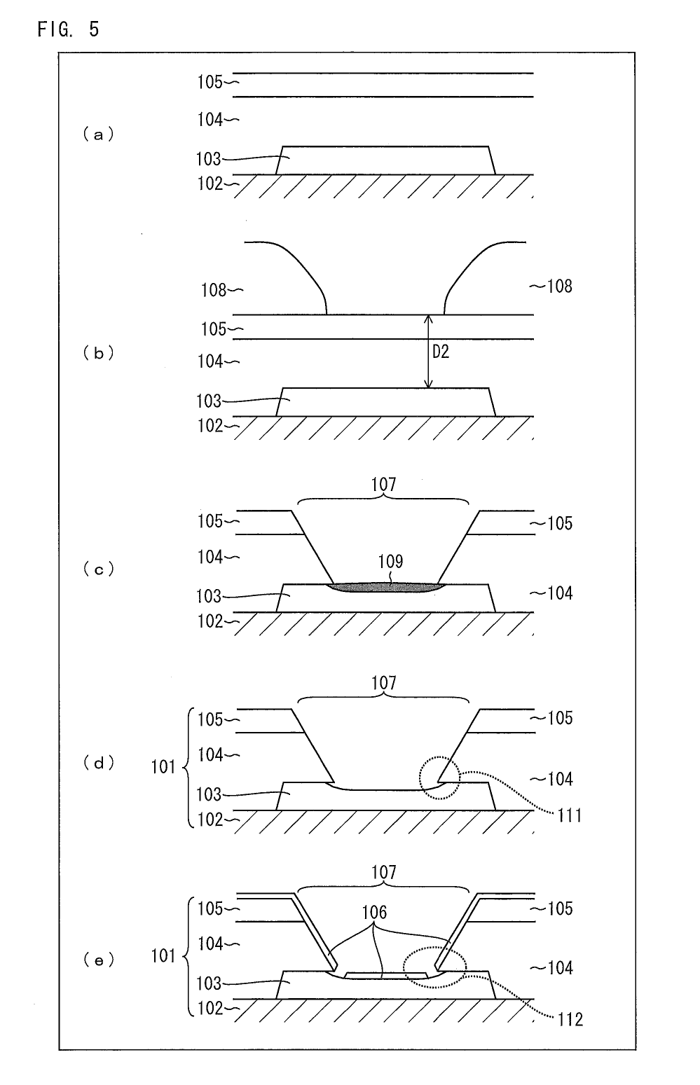

According to the present embodiment, after the formation of the gate insulating film 4, the hole 11 is thus formed in the gate insulating film 4. After the formation of the interlayer insulating film 5 on the gate insulating film 4 and in the hole 11, the hole 13 is formed in the interlayer insulating film 5 in the hole 11. That is, the contact hole 7 is formed in a multi-step manner. Therefore, in the present embodiment, a thickness D1 (see (e) of FIG. 5) of the interlayer insulating film 5, to which the etching is applied so as to finally expose the part of the Al alloy pad 3, is thinner than a combined thickness D2 (see (b) of FIG. 5) of (i) the interlayer insulating film 105 and (ii) the gate insulating film 104 to which films (i) and (ii) the etching is applied in a conventional method so as to form the contact hole 107 running through the interlayer insulating film 105 and the gate insulating film 104.

This causes a decrease in the time required for the etching applied to the interlayer insulating film 5 so as to expose the Al alloy pad 3 in the method of the present embodiment, as compared with the time required for the etching applied to form a contact hole in the conventional method. As such, the area of the electrically nonconductive layer 9 is reduced. This in turn causes a decrease in size of the overhang that is caused by the removal of the electrically nonconductive layer 9. In a case where the overhang is small, the disconnection is rarely caused even if the transparent electrode film 6 is formed on the overhang. As such, the occurrence of the contact fault can be prevented.

The time required for each etching applied to a corresponding insulating film varies depending on (i) a film thickness of the corresponding insulating film, (ii) a film quality (a film quality distribution) of the corresponding insulating film, (iii) a type of etching gas, and (iv) an etching condition.

For example, in a case where a refractive index of an insulating film (e.g., SiN) is high, the time required for etching becomes long. This causes an increase in the film thickness of the electrically nonconductive layer 9 caused on the surface of the Al alloy pad 3. Also, as early described, in the case where SF₆ is used as the etching gas, the etching time is increased, as compared with the case where CF₄ is used as the etching gas. This causes an increase in the film thickness of the electrically nonconductive layer 9 caused on the surface of the Al alloy pad 3. Further, if high RF power is supplied during the etching, then the electrically nonconductive layer 9 becomes thick.

For the reasons above, it is preferable that a film thickness of the outermost layer (the interlayer insulating film 5 in the present embodiment) for which the contact hole 7 is formed is 300 nm or less.

Further, in order to efficiently prevent the occurrence of the disconnection, it is preferable that the film thickness of the transparent electrode film 6 is at least 1.5 times greater than a film disposal amount (i.e., a film disposal thickness) obtained by removing, by an alkali treatment, the electrically nonconductive layer 9 caused on the surface of the Al alloy pad 3.

Further, it is preferable that a film thickness of an uppermost one (the interlayer insulating film 5 in the present embodiment) of a plurality of insulating films is thinner than a film thickness of at least one (the gate insulating film 4 in the present embodiment) of the rest of the plurality of insulating films.

Generally, an insulating film serves so as to provide an improvement in an insulation property (protection property). However, it is difficult for a thin insulating film to ensure a desired insulation property. In consideration, it is preferable that two or more insulating films are used as described in the present embodiment.

The insulating film is sometimes used to serve as a dielectric which forms retention capacitance. For example, a dielectric formed solely by a thin film of a final insulating film can form great storage capacitance, if it is provided between (i) a storage capacitor electrode provided in a gate layer and (ii) another storage capacitor electrode provided in a pixel electrode layer.

In the present embodiment, the hole 13 is formed in the interlayer insulating film 5 in such a manner that the entire hole 13 is located inside the hole 11. Alternatively, it is suitable that a hole formed after another hole(s) is formed in such a manner that at least a part of the hole is located inside an innermost one of the another hole(s).

The present invention is not limited to Embodiments 1 and 2, but may be altered by a skilled person in the art within the scope of the claims. That is, an embodiment derived from a proper combination of technical means altered as appropriate within the scope of the claims is also encompassed in the technical scope of the present invention.

It is preferable that the method of the present invention for manufacturing a wiring board further includes the step of forming in the contact hole, after the step of removing the electrically nonconductive layer, an electrically conductive layer which is in contact with the Al alloy layer.

With the arrangement, a wiring board can be manufactured in which it is ensured that the Al alloy layer and the electrically conductive layer are electrically connected with each other in the contact hole. As such, it is possible to provide the wiring board in which occurrence of contact fault is avoided.

It is preferable that the method of the present invention for manufacturing a wiring board is arranged so that: the etching is dry etching in which a fluorine-containing gas is used; and the electrically nonconductive layer is removed, in the step of removing the electrically nonconductive layer, by an alkali treatment.

With the arrangement, the contact hole can be efficiently formed. Also, the electrically nonconductive layer caused on the surface of the Al alloy layer by the dry etching, such as an Al fluoride and an Al oxide, can be efficiently removed by the alkali treatment.

Further, it is preferable that the method of the present invention of manufacturing a wiring board is arranged so as to further include the steps of: forming the contact hole, after forming an uppermost one of the plurality of insulating layers, by forming another hole in the uppermost one of the plurality of insulating layers within the hole, formed in one of the plurality of insulating layers which is formed under the uppermost one, by etching so as to expose a part of the Al alloy layer; and forming, after removing an electrically nonconductive layer caused on the surface of the Al alloy layer during the etching for the another hole, an electrically conductive layer, which is in contact with the Al alloy layer, in the contact hole.

With the arrangement, a wiring board is manufactured in which it is ensured that the Al alloy layer and the electrically conductive layer are electrically connected with each other in the contact hole. As such, it is possible to provide the wiring board in which occurrence of contact fault is avoided.

Further, it is preferable that the method of the present invention for manufacturing a wiring board is arranged so that: each of the etchings is a dry etching in which a fluorine-containing gas is used; and each of electrically nonconductive layers is removed by an alkali treatment

With the arrangement, the holes can be efficiently formed. Also, the electrically nonconductive layer caused on the surface of the Al alloy layer by dry etching, such as an Al fluoride and an Al oxide, can be efficiently removed by performing the alkali treatment.

### INDUSTRIAL APPLICABILITY

The present invention can be applied to manufacturing of a substrate of a display device such as a liquid crystal display device. Particularly, the present invention can be suitably applied to manufacturing of a TFT substrate.

### REFERENCE SIGNS LIST

1: wiring board
2: base layer
3: Al alloy pad (Al alloy layer)
4: gate insulating film (insulating layer, first insulating layer)
5: interlayer insulating film (insulating layer, second insulating layer)
6: transparent electrode film (electrically conductive layer)
7: contact hole
8: resist pattern
9: electrically nonconductive layer
10: region
11, 13: hole
14: wall surface
15, 16: resist pattern

1. A method for manufacturing a wiring board including an Al alloy layer provided on a base layer, an insulating layer provided on the Al alloy layer, and a contact hole whose opening part reaches a part of the Al alloy layer,
said method comprising the steps of:
(i) forming the contact hole in the insulating layer by etching so as to expose, in the contact hole, (a) at least a first part of an end of the Al alloy layer and (b) a second part of the base layer, the second part being adjacent to at least the first part; and
(ii) removing, after the step (i), an electrically nonconductive layer, caused by the etching, on a surface of the Al alloy layer.

2. The method as set forth in claim 1, further comprising the step of:
forming in the contact hole, after the step (ii), an electrically conductive layer which is in contact with the Al alloy layer.

3. The method as set forth in claim 1, wherein:
the etching is dry etching in which a fluorine-containing gas is used; and
the electrically nonconductive layer is removed, in the step (ii), by an alkali treatment.

4. A method for manufacturing a wiring board including an Al alloy layer provided on a base layer, a plurality of insulating layers provided on and above the Al alloy layer, and a contact hole whose opening part reaches the Al alloy layer,
said method comprising the steps of:
(i) forming, after forming a first insulating layer of the plurality of insulating layers, a first hole in the first insulating layer by etching so as to expose a first part of the Al alloy layer in the first hole; and
(ii) forming by etching, after forming a second insulting layer of the plurality of insulating layers on the first insulating layer so as to cover an exposed surface of the Al alloy layer, a second hole in the second insulating layer located within the first hole so as to expose a second part which is part of the first part of the Al alloy layer thus exposed,
an electrically nonconductive layer, caused by the etching on the surface of the Al alloy layer in the step (i), being removed in the step (i),
an electrically nonconductive layer, caused by the etching on the surface of the Al alloy layer in the step (ii), being removed in the step (ii).

5. A method as set forth in claim 4, further comprising the steps of:
(iii) forming the contact hole, after forming an uppermost one of the plurality of insulating layers, by forming another hole in the uppermost one of the plurality of insulating layers within the hole, formed in one of the plurality of insulating layers which is formed under the uppermost one, by etching so as to expose a part of the Al alloy layer; and
(iv) forming, after removing an electrically nonconductive layer caused on the surface of the Al alloy layer during the etching for the another hole, an electrically conductive layer, which is in contact with the Al alloy layer, in the contact hole.

6. The method as set forth in claim 4, wherein:
each of the etchings is a dry etching in which a fluorine-containing gas is used;
and
each of electrically nonconductive layers is removed by an alkali treatment.
